(19) United States
(12) Patent Application Publication
(10) Pub. No.: US 2016/0016209 A1
(43) Pub. Date: Jan. 21, 2016

(54) Quantum Levitation for Permanent Superlyophobic and Permanent Self-Cleaning Materials

(71) Applicant: University of Florida Research Foundation, Inc., Gainesville, FL (US)

(72) Inventors: Wolfgang M. Sigmund, Gainesville, FL (US); Christian David Bohling, Gainesville, FL (US)

(21) Appl. No.: 14/847,717

(22) Filed: Sep. 8, 2015

Related U.S. Application Data
(63) Continuation-in-part of application No. PCT/US2014/022578, filed on Mar. 10, 2014.
(60) Provisional application No. 61/775,036, filed on Mar. 8, 2013.

(51) Int. Cl. B08B 17/06; C23C 16/44; C23C 14/22

(52) U.S. Cl. CPC B08B 17/06; C23C 14/22; C23C 16/44

(57) ABSTRACT

A self-cleaning object comprises a substrate with a surface of a first material that has a high dielectric constant overlaid with an ultrathin layer of a second material with a lower dielectric constant than the first material. This self-cleaning object repels liquids or particulate solids that have a lower dielectric constant than the dielectric constant of the ultrathin layer. Another self-cleaning object comprises a substrate with a surface of a first material that has a very low dielectric constant overlaid with an ultrathin layer of a second material with a low dielectric constant that is higher than the first material. This self-cleaning object attracts gases and repels liquids or particulate solids.

### CROSS-REFERENCE TO RELATED APPLICATIONS

This application is a continuation-in-part of International Application No. PCT/US2014/022578, filed Mar. 10, 2014, which claims the benefit of U.S. Provisional Application Ser. No. 61/775,036, filed Mar. 8, 2013, the disclosures of which are hereby incorporated by reference in their entireties, including any figures, tables, or drawings.

### BACKGROUND OF INVENTION

The cleaning of surfaces is time-consuming and costly. Therefore, economic incentive exists for providing surfaces that have water, oil, and dirt repellency. The solution of the problem has been addressed by an effort to minimize the adhesion and/or wetting mechanisms that generally depend on surface-energy parameters that exist between two contacting surfaces. The goal is to lower the free surface energy that is generally the result of polar or chemical interactions. Where the free surface energies between two surfaces are very low, adhesion between the surfaces is very weak. When a material with high surface area is paired with a material with low surface energy, possible interactions must be considered. For example, when water is applied to a hydrophobic surface, marked lowering of the surface energy does not occur, and wetting of the surface is poor. Non-stick materials, such as, perfluorinated hydrocarbons, have a very low surface energy and have little possibility of specific interactions with most other substances that can result in adhesion. These traditional non-stick materials are not capable of suppressing van der Waals interactions. Accordingly, adhesion of a material to these surfaces is defined substantially by the contact area, where the smaller the contact area, the lower the adhesion.

Nature exploits this phenomenon for achieving a very low level of water adhesion by formation of small wax bumps on many leaves' surfaces to reduce the van der Waals contact area of a water droplet, such that the water droplets do not adhere well. This effect is known as the “Lotus effect” as it is commonly exhibited by lotus leaves. These surfaces are known as superhydrophobic surfaces and a considerable effort has been made towards the formation of superhydrophobic surfaces because of their potential applications, such as, anti-sticking, anti-contamination, and self-cleaning coatings. The textured superhydrophobic surface displays a water contact angle that is larger than 150° and has a low sliding angle, which is the critical angle where a water droplet of a defined mass rolls from the inclined surface.

Relatively little effort has been directed to the formation of superoleophobic, or superlyophobic, or even oleophobic surfaces that display contact angles greater than 90° but less than 150° with liquids other than water. Available superoleophobic surfaces are also superhydrophobic. The condition of being superoleophobic is useful for allowing a superhydrophobic surface to have an extended period of utility under real-world conditions, where an otherwise superhydrophobic surface would lose its self-cleaning property because of oily material accumulation that fills the texture of the surface.

Oil repellent surfaces are an engineering challenge because the surface tensions of oily liquids are usually in the range of 20-30 mN/m. The essential criterion, for having a surface with superoleophobicity, is to maintain the oil drops in a Cassie-Baxter (CB) state where vapor pockets are trapped underneath the liquid. The CB state depends on the surface's structure and the surface energy of the material. If the structure and surface area are insufficient, the meta-stable energetic state is transformed into Wenzel state.

Superoleophobic surfaces display geometric features having a re-entrant structure. The re-entrant structure implies that a line drawn vertically from the base solid surface through the geometric feature must proceed through more than one solid interface of that feature. Superoleophobic surfaces require a surface of sufficiently low surface energy relative to the surface energy of oil. Presently, oleophobic or superoleophobic surfaces require a fluorocarbon material at the surface to decrease the surface energy of the structured material sufficiently. The achievement of a superoleophobic surface is difficult with commercially viable fluorocarbon materials. These and other significant shortcomings inhibit the use of all existing self-cleaning surfaces that are superlyophobic. Unfortunately, the oil repellency of known superlyophobic surfaces is generally lost within 24 hours, and as self-cleaning relies on the availability of water, damaged superlyophobic surfaces lose their self-clean properties or lose their superhydrophobicity. Therefore, an alternate approach to superlyophobic surfaces construction is desirable.

Van der Waals (vdW) interactions are caused by a change in dipole moment arising from a shift of orbital electrons to one side of an atom or molecule, creating a similar shift in adjacent atoms or molecules. For like materials, the vdW forces are always attractive. However, repulsive forces are possible for certain unlike material combinations. Repulsive forces are responsible for the unique wetting property of liquid helium, which climbs up the wall of any containers, down the other side, and eventually completely leaves the container. Other examples of repulsive vdW forces are those that occur across thin liquid hydrocarbon films on alumina (see Blake, J. Chem. Soc. Faraday Trans. I 71 (1975) 192) and quartz (see Gee et al., J. Colloid Interface Sci. 131 (1989) 18) and at phase separation of polymer mixture solutions. (see van Oss et al. Colloid Polym. Sci. 257 (1979) 737) Superlyophobic surfaces that result in “quantum levitation” due to a repulsive vdW interaction have not been prepared.

### SUMMARY OF THE INVENTION

Embodiments of the invention are directed to a self-cleaning object that has a substrate having a surface of a first material having a relatively high dielectric constant and an ultrathin layer of a second material having a lower dielectric constant than that of the first material overlaid on the first surface and having a thickness of 1 to 10 nm. This second surface is one from which liquids, particulate solid, or even organism, which are of a third material having a lower dielectric constant than the dielectric constant of the ultrathin layer, are repelled. The surface of the self-cleaning object can be partitioned with re-entrant structures to act in a super-hydrophobic or super-oleophobic surface. The first material can be polydimethylsiloxane and the second material is polyethylene or a polyethylene equivalent, such as an alkyl silane, for an object to function as a dust or insect resistant object. In an embodiment of the invention, the second surface can be one where air or other gases, such as nitrogen, oxygen, and inert gases are attracted. For example, the first material can be an amorphous fluoropolymer and the second material can be a crystalline fluoropolymer.

Another embodiment of the invention is directed to a method of preparing an object with a self-cleaning surface, where an ultrathin layer of a second material is deposited on a substrate having a surface of a first material with a first dielectric constant, and where the second material has a lower dielectric constant than the first material. Deposition can be carried out by a self-assembly process, a solution deposition, PVD, CVD or ALD.

### BRIEF DESCRIPTION OF DRAWINGS

FIG. 1 shows a schematic of the orientation of three materials that have been considered for repulsive van der Waals systems in the prior art.

FIG. 2 shows a schematic of the structure of a permanent superlyophobic construction of a substrate with an ultrathin layer near a spherical levitated material, according to an embodiment of the invention.

FIG. 3A shows a composite plot of the dielectric response of various alcohols and FIG. 3B shows a composite plot of the dielectric response of water and various hydrocarbons for comparison with those of yttria and barium titanate.

FIG. 4 shows a composite plot of the dielectric response of various common metal oxides in comparison with those of yttria and barium titanate.

FIG. 5 is a table of Hamaker constants for various solvents and metal oxides for contact with an yttria ultrathin layer on a barium titanate, according to an embodiment of the invention.

FIG. 6 shows a composite plot of the dielectric response of various solids with those of bulk PDMS—thin film polyethylene object.

FIG. 7 shows a composite plot of the dielectric response of various liquids with those of bulk PDMS—thin film polyethylene object.

FIG. 8 shows a plot of C_{UV} constant for long chain alkanes as a function of chain length.

FIG. 9 shows a plot of the ω_{UV} constant for long chain alkanes as a function of chain length.

FIG. 10 shows a plot of the C_{IR} constant for long chain alkanes as a function of chain length.

### DETAILED DISCLOSURE

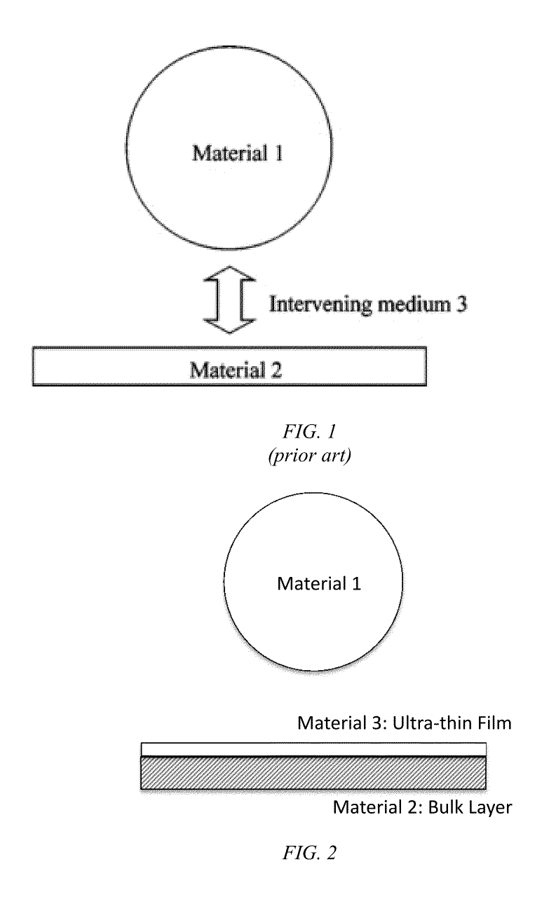

Embodiments of the invention are directed to “quantum levitation” where a surface attracts air, or other gas, much more strongly than any solid or liquid. Interactions in this system can be described by the materials' dielectric response functions (DRFs). The DRF of the surface is of first value, an intervening material has a DRF of a second value, and a levitated material to be repelled from the surface has a DRF of a third value, where the magnitude of the second value is between that of the first and third values. In this manner, the surface has the potential to remain untouched and clean at all times as a negative van der Waals interaction occurs. In an embodiment of the invention, the surface material is one that upon damage exposes a new layer of the material, such that after damage a fresh quantum-levitating surface is exposed at the damaged area. FIG. 1 shows a schematic representation of this relationship between the surface material (2) the intervening material (3) and the levitated material (1), where the levitated material, if a fluid, would assume the shape of a sphere and, if a solid, is most readily modeled as a sphere.

Dielectric response functions (DRF), or ∈(iξₘ), can be described using four constants in the following equation:

$$ɛ ( i {ξ}_{m} ) = 1 + \frac{{C}_{IR}}{1 + {( \frac{{ξ}_{m}}{{ω}_{IR}} )}^{2}} + \frac{{C}_{UV}}{1 + {( \frac{{ξ}_{m}}{{ω}_{UV}} )}^{2}} , \qquad ( 1 )$$

where C_{IR} and G_{UV} are the absorption strengths in the infrared (IR) and ultraviolet (UV) regions of the electromagnetic spectrum, respectively, and ω_{IR} and ω_{UV} the characteristic absorption frequencies in the IR and UV, respectively. The value, ξₘ, is given by the equation:

$${ξ}_{m} = m \frac{4 {π}^{2} kT}{h} , \qquad ( 2 )$$

where k is Boltzmann's constant, T is the temperature in Kelvin, and m is an integer.

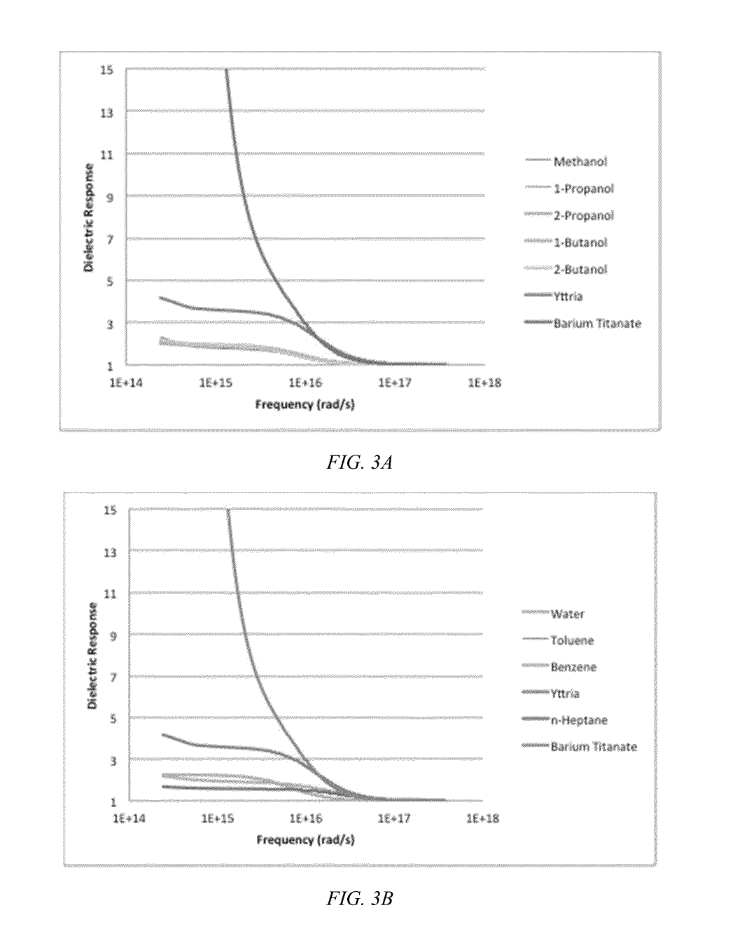

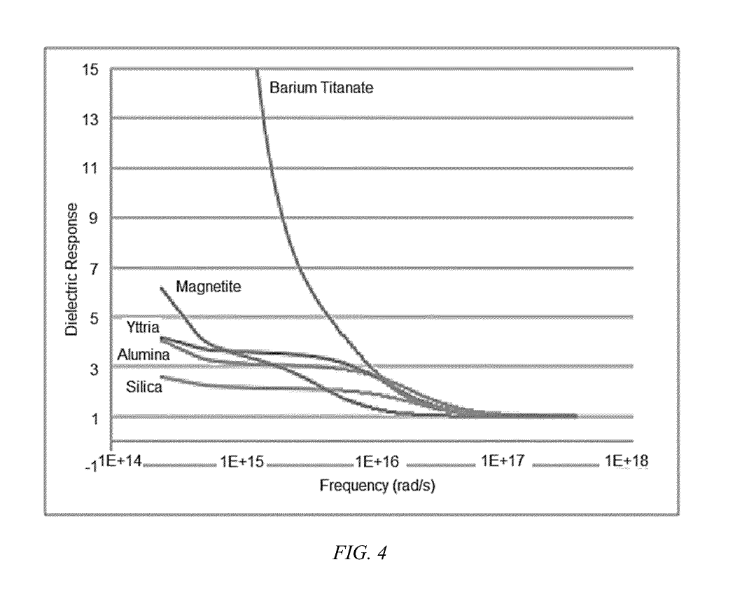

In an embodiment of the invention, the surface material is a high dielectric ceramic, the intervening material is an ultrathin film of less than 10 nm with an intermediate dielectric, and the repelled liquid or the solid has a lower dielectric. A very high dielectric ceramic can be coated with a thin film of a lower dielectric ceramic. For example, the superlyophobic surface can be, but is not limited to: barium titanate (∈₀=2400) overlaid with an ultrathin layer of TiO₂, Y₂O₃, ZnO, PbS, MgO, or Si₃N₄; strontium titanate (∈₀=311) overlaid with an ultrathin layer of ZnO, MgO, Y₂O₃, silica, or magnetite; titania (∈₀=114) overlaid with an ultrathin layer of ZnO, MgO, or Y₂O₃; or yttria (∈₀=11.8) overlaid with an ultrathin layer of MgO or silica. The DRFs for the combination of Barium Titanate overlaid with an ultrathin layer of Y₂O₃, and various liquids to be repelled, are plotted in FIGS. 3A and 3B. The DRFs for the combination of barium titanate overlaid with an ultrathin layer of Y₂O₃, with common particulate metal oxide solids to be repelled, are plotted in FIG. 4.

A Hamaker constant, J, can be calculated from the energy of the vdW interactions between two macroscopic bodies by summing the interactions between all molecular pairs of the two bodies. The vdW energy for the interaction between a sphere and a flat surface separated by a distance, D, is given by:

$${V}_{vdW} ( D ) = - \frac{JR}{6 D} , \qquad ( 3 )$$

where R is the radius of a sphere and J is the Hamaker constant, which is defined as:

J=π²Cρ₁ρ₂ (4),

where ρ₁ and ρ₂ are the number of atoms per unit volume in the two bodies and C is the coefficient in the atom-atom pair potential.

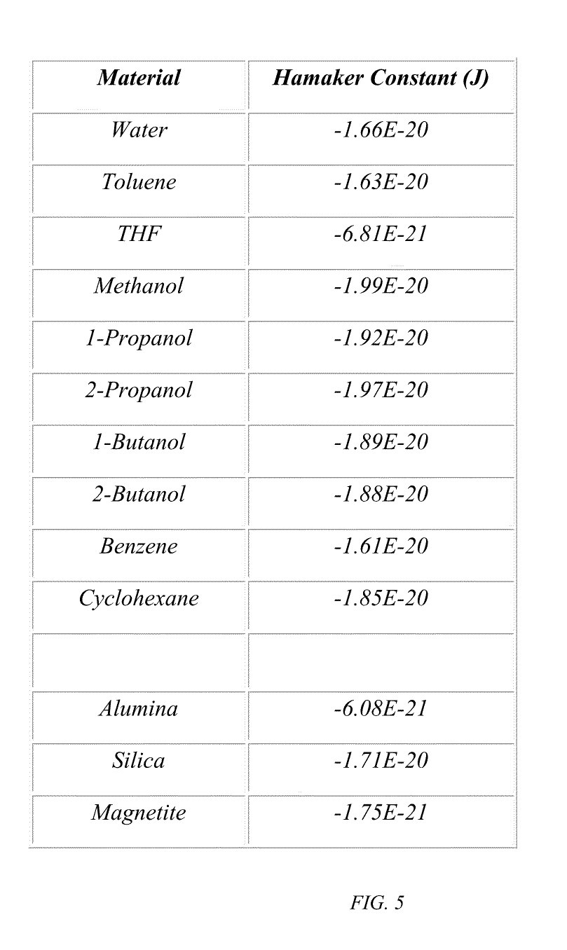

FIG. 5 is a table of calculated Hamaker constants for combinations of various liquids and solids for the systems of FIGS. 3 and 4, where the surface is barium titanate overlaid with an yttria layer of 10 nm. In all cases, the Hamaker constants are negative values. The J value for water over this Yttria over layer is calculated to be −1.66E-20, as opposed to water directly on barium titanate in air where the value of J is: 8.72E-20.

In an embodiment of the invention, the surface is partitioned with re-entrant structures to provide a “lotus effect” in addition to having an ultrathin over layer to enhance repulsion of other liquids and solids at the interface. In embodiments of the invention, the surface material is the bulk material of the substrate or is a relatively thick layer of a material on the substrate, for example, a layer of more than about 10 nm, more than about 15 nm, more than about 20 nm, more than about 50 nm, more than about 100 nm, or more than about 1,000 nm.

In an embodiment of the invention, a permanent self-cleaning object is prepared by providing a substrate or thick layer of a high dielectric material, coating the surface of the high dielectric material with an ultrathin layer of a material with a lower dielectric constant than the high dielectric material. The ultrathin layer is less than or equal to about 10 nm in thickness. The substrate can be flat or partitioned to have re-entrant structures or other features to provide a “lotus effect.” Re-entrant structures are geometric features, such as mushroom heads, micro-hoodoos, or horizontally aligned cylindrical rods. The re-entrant structure implies that a line drawn vertically, from the base solid surface through the geometric feature, must proceed through more than one solid interface of that feature. The ultrathin layer can be deposited by chemical vapor deposition (CVD), atomic layer deposition (ALD) or other method capable of forming a layer of 10 nm or less.

In another embodiment of the invention, an attractive interaction exists with a gas, for example air, and a repulsive interaction exists with liquids and solids. In an embodiment of the invention very low dielectric materials, for example, an amorphous fluoropolymer, for example, Dupont™ Teflon® AF, is a substrate surface, which is coated with an ultrathin film of a crystalline polytetrafluoroethylene Teflon®, which has a higher dielectric constant than the substrate surface. The ultrathin film is a few nanometers in thickness, for example, less than 10 nm. This structure possesses a positive Hamaker constant, promoting van der Waals attraction between this surface and a gas, such as air. As almost all other materials interact with a negative Hamaker constant, quantum repulsion exists with the surface. Therefore, the surface of the self-cleaning object remains untouched and clean at all times due to quantum attraction of the gas and quantum repulsion of liquids and solids, displaying permanent superhydrophobicity. Currently available superhydrophobic surfaces, including those with Lotus and Plastron surface architectures, lose their superhydrophobicity when the air dissolves in water upon immersion after about 24 hours due to La Place pressure. In contrast, the positive Hamaker constant surface, according to an embodiment of the invention, attracts air, which opposes the La Place pressure, and keeps air trapped at the superhydrophobic surface.

In an embodiment of the invention, materials with a repulsive van der Waals coating can be placed on the surfaces of household appliances for the prevention of dust build-up on windows, fan blades, and other devices where an omniphobic surface is not required. This lowers material combination requirements for the low-to-high repulsion conditions described above, as solids typically have relatively high dielectric constants and corresponding dielectric response functions. Surface for the repulsion of dust can be surface that bead and shed water and other liquids, as even though liquids are not repelled, the surface is characterized by a dramatically reduced Hamaker constant, limiting van der Waals attraction to the surface.

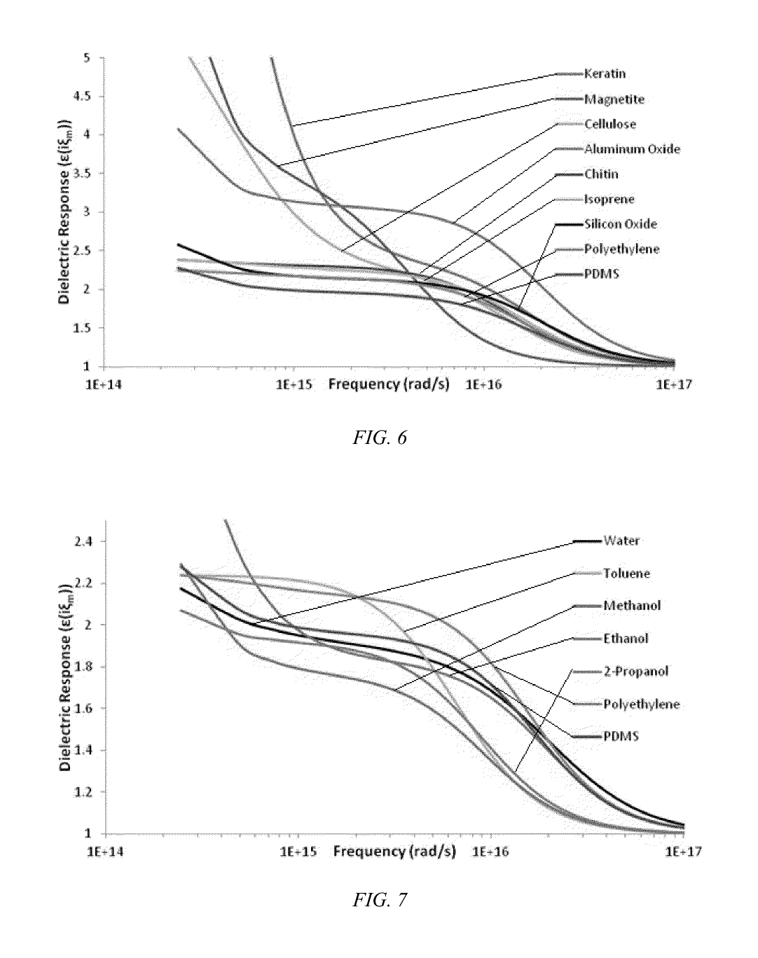

For example, a polydimethylsiloxane (PDMS) bulk substrate topped by a polyethylene, polypropylene, polystyrene, or an equivalent thereof as a thin film can be considered. The thin films of 1-10 nm can be deposited with a silane, where the silane portion of the molecule bonds with the PDMS, with the thin film functionality residing at the surface. The PDMS can have sufficient SiOH groups, either as formed in a gelling system or formed by a surface hydrolysis, for example an acid or base catalyzed hydrolysis of the surface. The functional group can be varied in length bonded to the PDMS. A simple alkyl chain, branched alkyl chain, and alkyl chain with a terminal phenyl unit are thin film equivalents of polyethylene, polypropylene, and polystyrene, respectively. The silane can have one to three alkoxy, halo, H, or dialkylamino groups for reaction with silanol groups of PDMS. Example dielectric response functions for a bulk PDMS—polyethylene thin film system and potential contacting materials are given in the plots of FIG. 6 and FIG. 7 for solids and liquids, respectively.

Estimation of Hamaker constants for the system of two polymers in bulk substrate—thin film orientation, can be calculated from optical data derived from their bulk properties, although there is a small inherent degree of error stemming from the thin film deviation from bulk material. Considering a bulk PDMS-polyethylene thin film system, estimates can be made from organic liquid thin films that correspond to a silane substituents chain length. The difference in the PDMS—organic liquid values allows prediction of the Hamaker constants potential range for these systems. Even in cases where the Hamaker constant is positive, indicating attraction, the magnitude of the predicted Hamaker constant reduces over the interaction with the bulk PDMS substrate absent the thin film.

Common household particulates, as exemplified by the values for silicon oxide, aluminum oxide, and iron oxide, the most common mineral particulates, are used and data for isoprene, cellulose, keratin, and chitin, which respectively represent oils commonly found in human skin, clothing particulates, hair and shed skin cells, and dust mites or other small insects cells, are estimated from optical data. Values for other common liquids are also calculated. The calculated Hamaker constants are shown in Table 1-Table 5, below. The modeled system, displaying consistently repulsive Hamaker constants for solid contacting materials, is bulk PDMS—polyethylene thin film objects, as indicated in Table 1. Tables 2 and 3 suggest that as the silane becomes longer, the Hamaker constants more closely resemble that of a polyethylene thin film. As suggested in Tables 4 and 5, polyethylene thin films are preferable to those of polypropylene and polystyrene.

TABLE 1
Hamaker constants for a bulk PDMS - thin film
polyethylene - contacting material system.

| Contacting | Ham. | Contacting | Ham. |
|---|---|---|---|
| Compound | Constant (zJ) | Compound | Constant (zJ) |
| Air | 4.68 | Alumina | −3.03 |
| Water | 0.80 | Silica | −0.36 |
| Toluene | 1.64 | Magnetite | 1.33 |
| Methanol | 2.32 | Isoprene | −0.33 |
| Ethanol | 0.84 | Cellulose | −0.01 |
| 2-Propanol | 1.86 | Keratin | −1.12 |
| | | Chitin | −0.23 |

TABLE 2
Hamaker constants for a bulk PDMS - thin film n-heptane (estimating
a short chain silane) - contacting material system.

| Contacting | Ham. | Contacting | Ham. |
|---|---|---|---|
| Compound | Constant (zJ) | Compound | Constant (zJ) |
| Air | −6.16 | Alumina | 9.12 |
| Water | 2.85 | Silica | 4.31 |
| Toluene | 1.92 | Magnetite | 4.39 |
| Methanol | 0.77 | Isoprene | 4.62 |
| Ethanol | 2.65 | Cellulose | 5.60 |
| 2-Propanol | 1.27 | Keratin | 7.71 |
| | | Chitin | 4.68 |

TABLE 3
Hamaker constants for a bulk PDMS - thin film dodecane (estimating
a medium chain silane) - contacting material system.

| Contacting | Ham. | Contacting | Ham. |
|---|---|---|---|
| Compound | Constant (zJ) | Compound | Constant (zJ) |
| Air | 3.28 | Alumina | −2.79 |
| Water | 0.50 | Silica | −0.51 |
| Toluene | 2.29 | Magnetite | 2.95 |
| Methanol | 2.53 | Isoprene | −0.04 |
| Ethanol | 0.74 | Cellulose | 0.99 |
| 2-Propanol | 2.15 | Keratin | −0.06 |
| | | Chitin | 0.23 |

TABLE 4
Hamaker constants for a bulk PDMS - thin film
polypropylene - contacting material system.

| Contacting | Ham. | Contacting | Ham. |
|---|---|---|---|
| Compound | Constant (zJ) | Compound | Constant (zJ) |
| Air | 15.40 | Alumina | −8.07 |
| Water | 3.32 | Silica | 0.43 |
| Toluene | 8.46 | Magnetite | 7.90 |
| Methanol | 9.47 | Isoprene | 1.55 |
| Ethanol | 4.25 | Cellulose | 2.93 |
| 2-Propanol | 8.50 | Keratin | −1.14 |
| | | Chitin | 2.14 |

TABLE 5
Hamaker constants for a bulk PDMS - thin film
polystyrene - contacting material system.

| Contacting | Ham. | Contacting | Ham. |
|---|---|---|---|
| Compound | Constant (zJ) | Compound | Constant (zJ) |
| Air | 9.24 | Alumina | −4.53 |
| Water | 1.99 | Silica | 0.23 |
| Toluene | 3.32 | Magnetite | 2.10 |
| Methanol | 4.46 | Isoprene | 0.19 |
| Ethanol | 2.18 | Cellulose | 0.25 |
| 2-Propanol | 3.78 | Keratin | −1.77 |
| | | Chitin | 0.29 |

In another embodiment of the invention, live insect traps are constructed based on repulsive van der Waals forces where, for example, bed bugs are inhibited simply by surfaces that the insect is unable to find a grip point to walk across a surface. The repulsive van der Waals forces of a surface can be used to prevent access, for example, from the floor of a room to the walls or furniture legs. Insects often have materials present in their exoskeleton, including epicuticular waxes and other compounds, and these materials can have a repulsive van der Waals force when associated with the traps surface of an ultrathin film.

Considering bed bugs, extermination of an infestation is difficult as the insect is not susceptible to typical insecticides. The current best mode of extermination is to raise the ambient temperature to above 115° F., or below 0° F., for an extended period of time. Traps are often not feasible due to a bed bug's extreme resilient to lack of food, often surviving for several months between feeding, allowing for eventual evasion of physical traps. Trap based on repulsive van der Waals forces function by a bed bug's inability to find a grip point for walking across the surface, or by preventing access, for example, from the floor of a room to the walls or furniture legs.

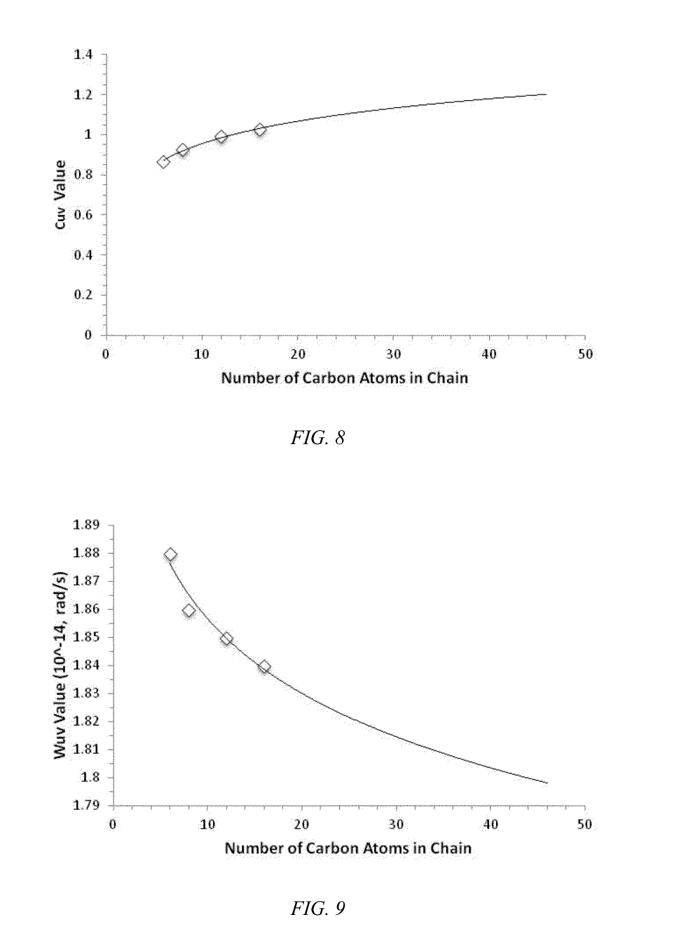

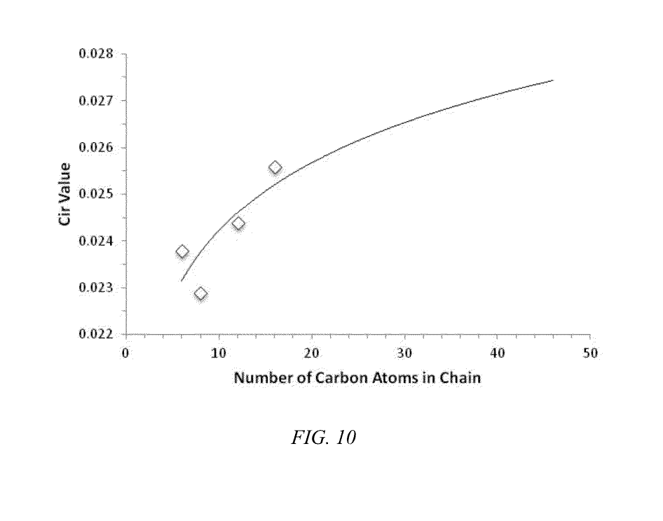

In the case of bed bugs, Cimex lectularius, epicuticular materials are typically an assortment of long chain alkanes between 24 and 33 carbons in length, some functionalized by a single methyl group. A list of the compounds present and their relative abundances is given in Table 66, below. The dielectric response functions of these materials can be extrapolated from the values for alkanes of shorter chain lengths for which optical constants have been reported. Trend lines provide the optical constants required for dielectric response functions are extrapolated from the data for hexane, octane, dodecane, and hexadecane, as shown in FIGS. 8 through 10, resulting in the calculated optical constants given in Table7. The trend lines provided are logarithmic, where it is assumed that as carbon chain length increase, the values for the optical constants approaches a limit where additional carbons do not significantly change the optical response. A constant value of 5.51E14 rad/s is predicted for the ω_{IR} value for all compounds, as the infrared absorption frequency should not change significantly when carbon chain length is increased.

TABLE 6
Epicuticular hydrocarbons in Cimex lectularius.

| Compound | No. of Carbons | Abundancy |
|---|---|---|
| n-Tetracosane | 24 | 0.08% |
| n-Pentacosane | 25 | 0.20% |
| n-Hexacosane | 26 | 0.28% |
| n-Heptacosane | 27 | 6.30% |
| n-Octacosane | 28 | 2.75% |
| n-Nonacosane | 29 | 31.70% |
| n-Triacontane | 30 | 4.91% |
| n-Hentriacontane | 31 | 24.13% |
| n-Dotriacontane | 32 | 3.13% |
| n-Tritriacontane | 33 | 3.19% |

TABLE 7
Predicted optical constants for long-chain alkanes
present in the exoskeleton of bed bugs.

| Compound | C_{UV} | ω_{UV} | C_{IR} | ω_{IR} |
|---|---|---|---|---|
| n-Tetracosane | 1.097 | 1.823 | 0.026 | 5.51 |
| n-Pentacosane | 1.103 | 1.822 | 0.026 | 5.51 |
| n-Hexacosane | 1.110 | 1.820 | 0.026 | 5.51 |
| n-Heptacosane | 1.116 | 1.819 | 0.026 | 5.51 |
| n-Octacosane | 1.122 | 1.817 | 0.026 | 5.51 |
| n-Nonacosane | 1.127 | 1.816 | 0.026 | 5.51 |
| n-Triacontane | 1.133 | 1.815 | 0.027 | 5.51 |
| n-Hentriacontane | 1.138 | 1.813 | 0.027 | 5.51 |
| n-Dotriacontane | 1.143 | 1.812 | 0.027 | 5.51 |
| n-Tritriacontane | 1.148 | 1.811 | 0.027 | 5.51 |

As shown in Tables 8-10, below, Hamaker constants for the contact of bed bug epicuticular wax with the described surfaces are much reduced, or even inverted, which predicts repulsion. These combinations can be used as a trap mechanism to prevent insect migration by eliminating their ability to move across a surface.

TABLE 8
Predicted Hamaker constants for long-chain alkanes
present in the exoskeleton of bed bugs contacting
a bulk Teflon AF - Teflon thin film surface.

| | Hamaker | | Hamaker |
|---|---|---|---|
| Compound | Constant (zJ) | Compound | Constant (zJ) |
| Tetracosane | 0.76 | Nonacosane | 0.49 |
| Pentacosane | 0.70 | Triacontane | 0.44 |
| Hexacosane | 0.65 | Hentriacontane | 0.40 |
| Heptacosane | 0.59 | Dotriacontane | 0.35 |
| Octacosane | 0.54 | Tritriacontane | 0.31 |

TABLE 9
Predicted Hamaker constants for long-chain alkanes
present in the exoskeleton of bed bugs contacting
a bulk PDMS - LDPE thin film surface.

| | Hamaker | | Hamaker |
|---|---|---|---|
| Compound | Constant (zJ) | Compound | Constant (zJ) |
| Tetracosane | −0.14 | Nonacosane | −0.23 |
| Pentacosane | −0.16 | Triacontane | −0.25 |
| Hexacosane | −0.18 | Hentriacontane | −0.26 |
| Heptacosane | −0.19 | Dotriacontane | −0.28 |
| Octacosane | −0.21 | Tritriacontane | −0.29 |

TABLE 10
Predicted Hamaker constants for long-chain alkanes
present in the exoskeleton of bed bugs contacting
a bulk PDMS - polystyrene thin film surface.

| | Hamaker | | Hamaker |
|---|---|---|---|
| Compound | Constant (zJ) | Compound | Constant (zJ) |
| Tetracosane | 0.70 | Nonacosane | 0.52 |
| Pentacosane | 0.66 | Triacontane | 0.49 |
| Hexacosane | 0.62 | Hentriacontane | 0.46 |
| Heptacosane | 0.59 | Dotriacontane | 0.43 |
| Octacosane | 0.56 | Tritriacontane | 0.40 |

All publications referred to or cited herein are incorporated by reference in their entirety, including all Figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

We claim:

1. A self-cleaning object, comprising:
a substrate having a first surface of a first material having a high dielectric constant; and
an ultrathin layer of a second material having a lower dielectric constant than that of the first material, where the ultrathin layer is overlaid on the first surface and has a thickness of 1 to 10 nm, and whereby a liquid, a particulate solid, or an organism, the surface layer thereof being of a third material having a lower dielectric constant than the dielectric constant of the ultrathin layer, is repelled from the second surface of the second material.

2. The self-cleaning object of claim 1, wherein the first material is the bulk of the substrate or is a thick layer of more than 10 nm on the bulk of the substrate.

3. The self-cleaning object of claim 1, wherein the first material is barium titanate and the second material is TiO₂, Y₂O₃, ZnO, PbS, MgO, or Si₃N₄.

4. The self-cleaning object of claim 1, wherein the first material is strontium titanate and the second material is ZnO, MgO, Y₂O₃, silica, or magnetite.

5. The self-cleaning object of claim 1, wherein the first material is titania and the second material is ZnO, MgO, or Y₂O₃.

6. The self-cleaning object of claim 1, wherein the first material is yttria and the second material is MgO or silica.

7. The self-cleaning object of claim 1, wherein the surface of the substrate is partitioned with re-entrant structures.

8. The self-cleaning object of claim 1, wherein the first material is polydimethylsiloxane and the second material is polyethylene or a polyethylene equivalent.

9. The self-cleaning object of claim 8, wherein the polyethylene equivalent is an alkyl silane.

10. The self-cleaning object of claim 1, wherein air or other gases are attracted to the second surface.

11. The self-cleaning object of claim 10, wherein the first material is an amorphous fluoropolymer and the second material is a crystalline fluoropolymer.

12. The self-cleaning object of claim 11, wherein the amorphous fluoropolymer is Teflon® AF and the second material is Teflon®.

13. A method of preparing an object with a self-cleaning surface according to claim 1, comprising:
providing a substrate having a surface of a first material with a first dielectric constant; and
depositing an ultrathin layer of a second material having a lower dielectric constant than the first material, wherein the ultrathin layer is overlaid on the first surface.

14. The method of claim 13, wherein the thickness of the ultrathin layer is 10 nm or less.

15. The method of claim 13, wherein deposition comprises self assembly, solution deposition, PVD, CVD or ALD.
